(19) United States
(12) Patent Application Publication
(10) Pub. No.: US 2026/0282598 A1
(43) Pub. Date: Sep. 17, 2026

(54) SOLAR CELL, METHOD FOR PREPARING SOLAR CELL, AND SOLAR CELL PRODUCTION LINE

(71) Applicant: LAPLACE Renewable Energy Technology Co., Ltd., Shenzhen (CN)

(72) Inventors: Wei Fan, Shenzhen (CN); Wu Zhang, Shenzhen (CN); Qun Liu, Shenzhen (CN)

(21) Appl. No.: 19/671,539

(22) Filed: May 8, 2026

(30) Foreign Application Priority Data
Aug. 8, 2025 (CN) 202511116017.8

(51) Int. Cl. H10F 77/70; H10F 71/00; H10F 77/164; H10F 77/20

(52) U.S. Cl. CPC H10F 77/703; H10F 71/129; H10F 71/134; H10F 77/1642; H10F 77/215

(57) ABSTRACT

Embodiments of the present disclosure relate to a solar cell, a method for preparing the solar cell, and a solar cell production line. The method includes providing a stack including an N-type silicon substrate having a boron-doped polysilicon layer near a first surface, with a tunneling oxide layer, a phosphorus-doped polysilicon layer, and a mask layer sequentially stacked as stated on an opposite second surface; forming through holes in the mask layer to expose the phosphorus-doped polysilicon layer; forming grooves at the through holes that extend through the phosphorus-doped polysilicon layer and the tunneling oxide layer and partially extend into the N-type silicon substrate, thereby separating a surface of the stack provided with the phosphorus-doped polysilicon layer into spaced emitter regions, and removing the mask layer.

### FIELD

The subject matter herein generally relates to the field of photovoltaic technology, specifically solar cells, methods for preparing solar cells, and solar cell production lines.

### BACKGROUND

In conventional tunnel oxide passivated contact (TOPCon) solar cells, a back side optical utilization efficiency of the TOPCon solar cells is low, and a bifacial utilization of the TOPCon solar cells needs to be improved.

Therefore, there is room for improvement in the art.

### BRIEF DESCRIPTION OF THE DRAWINGS

Implementations of the present disclosure will now be described, by way of embodiment, with reference to the attached figures.

FIG. 1 is a flowchart of a method for preparing a solar cell according to an embodiment of the present disclosure.

FIG. 2 is a schematic structural diagram of an N-type silicon substrate provided in the method showing in FIG. 1.

FIG. 3 is a schematic diagram showing a structure obtained after texturing the N-type silicon substrate in FIG. 2.

FIG. 4 is a schematic diagram showing a structure obtained after boron doping the N-type silicon substrate in FIG. 3.

FIG. 5 is a schematic diagram showing a structure obtained after removing a borosilicate glass layer from a second surface of the N-type silicon substrate in FIG. 4 and polishing the second surface.

FIG. 6 is a schematic diagram showing a structure obtained after forming a tunnel oxide layer, a phosphorus-doped polycrystalline silicon layer, and a mask layer on the second surface of the N-type silicon substrate in FIG. 5.

FIG. 7 is a schematic diagram showing a structure obtained after forming through holes in the mask layer in FIG. 6.

FIG. 8 is a schematic diagram showing a structure obtained after forming grooves at the through holes in FIG. 7 and removing the mask layer.

FIG. 9 is a schematic diagram showing a structure obtained after forming a front passivation layer, a back passivation layer, a front anti-reflection layer, and a back anti-reflection layer on the structure in FIG. 8.

FIG. 10 is a schematic structural diagram showing a solar cell obtained after forming front grid lines and back grid lines on the structure in FIG. 9.

FIG. 11 is a schematic diagram of a solar cell production line according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein may be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

The term “comprising” when utilized, means “including, but not necessarily limited to”; it specifically indicates open-ended inclusion or membership in the so-described combination, group, series, and the like. The disclosure is illustrated by way of example and not by way of limitation in the figures of the accompanying drawings in which like references indicate similar elements. It should be noted that references to “an” or “one” embodiment in this disclosure are not necessarily to the same embodiment, and such references can mean “at least one”.

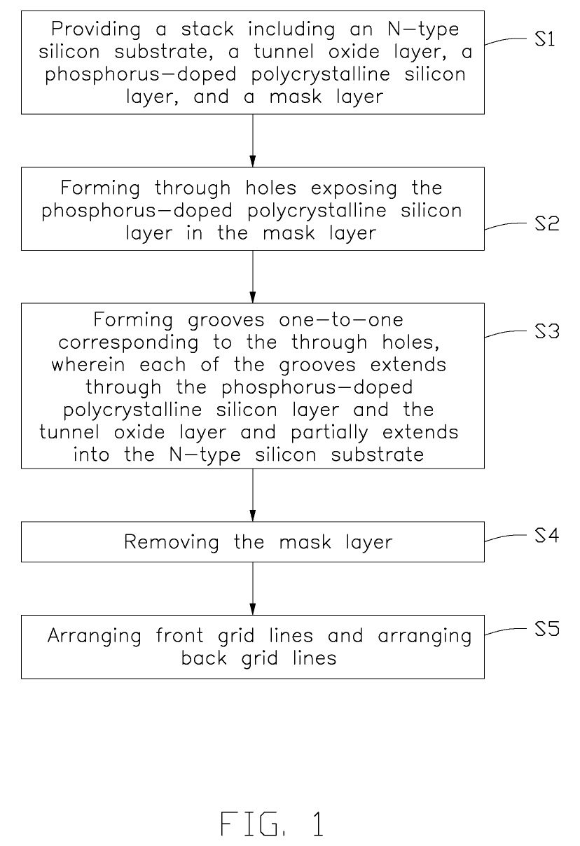

FIG. 1 is a flowchart of a method for preparing a solar cell according to an embodiment of the present disclosure. The method is provided by way of embodiment, as there are a variety of ways to carry out the method. The method described below can be carried out using the configurations illustrated in FIGS. 1-10 for example, and various elements of these figures are referenced in explaining the method. Each block in this method represents one or more processes, methods, or subroutines, carried out in the method. Additionally, the illustrated order of blocks is by example only and the order of the blocks can change. The method can begin at block S1 of FIG. 1.

In block S1, a stack is provided, wherein the stack includes an N-type silicon substrate, a tunnel oxide layer, a phosphorus-doped polycrystalline silicon layer, and a mask layer.

In some embodiments, the block S1 includes the following steps S11 to S15.

Step S11: providing an N-type silicon substrate.

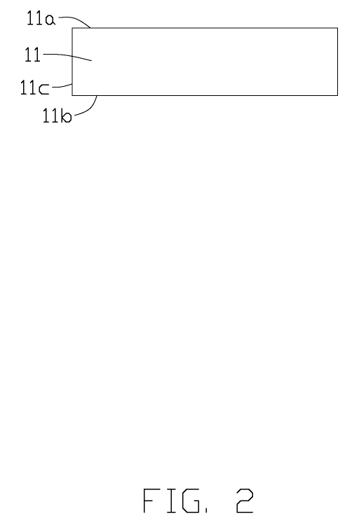

As shown in FIG. 2, the N-type silicon substrate 11 has a first surface 11a, a second surface 11b, and a side surface 11c. The second surface 11b is opposite to the first surface 11a. The side surface 11c connects the second surface 11b and the first surface 11a. The N-type silicon substrate 11 is an N-type monocrystalline silicon wafer.

In some embodiments, the N-type silicon substrate 11 is doped with an N-type doping element, and the N-type doping element may be at least one of group V elements such as phosphorus (P) element, bismuth (Bi) element, antimony (Sb) element, and arsenic (As) element.

Step S12: texturing the N-type silicon substrate.

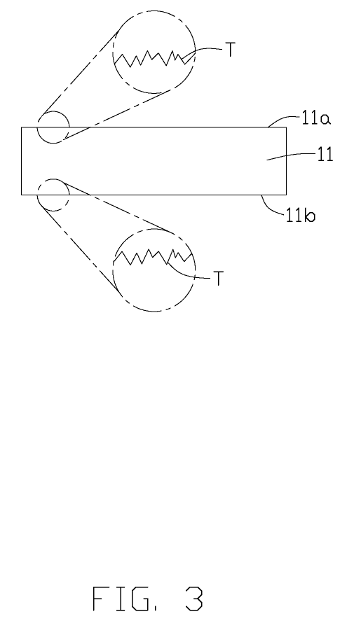

As shown in FIG. 3, after texturing, textured structures T are formed on each the first surface 11a of the N-type silicon substrate 11 and the second surface 11b of the N-type silicon substrate 11.

The purpose of texturing the N-type silicon substrate 11 is to form an uneven textured structures T, increasing a surface area of the silicon substrate and creating light-trapping structures that enhance absorption of sunlight and reduce reflection.

In some embodiments, a texturing equipment (such as a wet-process station) is used to form textures on the surface of the N-type monocrystalline silicon wafer.

In some embodiments, tested with a D8 reflectance tester, a reflectance of the surface of the N-type silicon substrate after texturing is less than 11%.

Step S13: boron doping on the N-type silicon substrate.

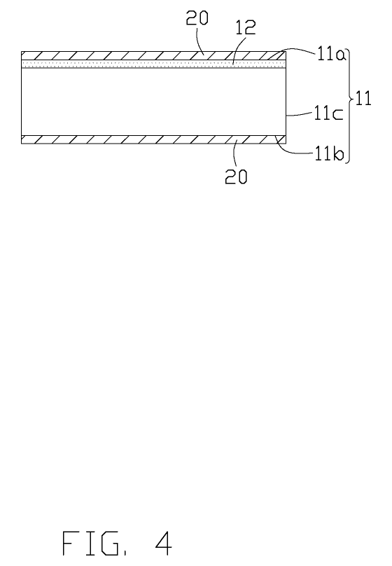

As shown in FIG. 4, after boron doping, a boron-doped polycrystalline silicon layer 12 is formed in the N-type silicon substrate 11 at a depth close to the first surface 11a. Additionally, in step S13, a borosilicate glass layer (BSG) 20 is further formed on the first surface 11a, the second surface 11b, and the side surface 11c of the N-type silicon substrate 11. The boron-doped polycrystalline silicon layer 12 and the BSG layer 20 on the side surface 11c are omitted in FIG. 4.

In some embodiments, boron doping on the N-type silicon substrate includes performing boron diffusion on the N-type silicon substrate and performing high-temperature oxidation treatment on the N-type silicon substrate.

In some embodiments, a boron doping equipment is used to dope a dopant element with a boron source on a side of the first surface 11a of the N-type silicon substrate 11. The boron doping equipment may include a boron diffusion standalone station, or a combination of a boron diffusion station and an oxidation station. The boron source includes one or more precursors such as BCl₃, BBr₃, B₂H₆, or trimethylboron. During boron diffusion, the BSG layer 20 forms first on the outermost surfaces (including the first surface 11a, the second surface 11b, and the side surface 11c) of the N-type silicon substrate 11, and the boron element in the BSG layer 20 gradually diffuses into the interior of the N-type silicon substrate 11 to a certain depth, forming a p+ layer (i.e., the boron-doped polycrystalline silicon layer 12). That is, the P+ layer is formed inside the N-type silicon substrate 11 corresponding to the first surface 11a, the second surface 11b and the side surface 11c. The BSG layer 20 is formed outside the p+ layer corresponding to the first surface 11a and is wrap-plated on the second surface 11b and the side surface 11c.

In some embodiments, by adjusting process parameters such as time and temperature during boron doping, a sheet resistance of the first surface 11a of the N-type silicon substrate 11 is controlled to between 200 ohm/sq and 800 ohm/sq (e.g., between 200 ohm/sq and 300 ohm/sq, between 300 ohm/sq and 400 ohm/sq, between 400 ohm/sq and 500 ohm/sq, between 500 ohm/sq and 600 ohm/sq, between 600 ohm/sq and 700 ohm/sq, between 700 ohm/sq and 800 ohm/sq).

In some embodiments, a thickness of the BSG layer 20 on the first surface 11a is controlled to between 70 nm and 110 nm (e.g., between 70 nm and 80 nm, between 80 nm and 90 nm, between 90 nm and 100 nm, between 100 nm and 110 nm). A surface concentration of boron is controlled to be between 2×10¹⁸ cm⁻³ and 8×10¹⁸ cm⁻³ (e.g., between 2×10¹⁸ cm⁻³ and 4×10¹⁸ cm⁻³, between 4×10¹⁸ cm⁻³ and 6×10¹⁸ cm⁻³, between 6×10¹⁸ cm⁻³ and 8×10¹⁸ cm⁻³).

In some embodiments, the boron diffusion is controlled to be performed within a first temperature range, and the high-temperature oxidation treatment is controlled to be performed within a second temperature range, wherein a minimum value of the second temperature range is greater than a maximum value of the first temperature range. Exemplarily, the first temperature range is between 700°C and900°C (e.g., between 700°C and750°C, between 750°C and800°C, between 800°C and850°C, between 850°C and900°C), and the second temperature range is 950°C and1050°C (e.g., between 950°C and980°C, between 980°C and1000°C, between 1000°C and1050°C).

In some embodiments, the boron doping equipment includes the combination of the boron diffusion station and the oxidation station. Boron diffusion and high-temperature oxidation require placing the N-type silicon substrate 11 sequentially in the boron diffusion station and the oxidation station, that is, in two separate processes. The oxidation station can be an annealing furnace, a gettering furnace, etc.

In some embodiments, in the above two processes, a temperature of boron diffusion is controlled to between 700°C and 900°C (e.g., between 700°C and 750°C, between 750°C and 800°C, between 800°C and 850°C, between 850°C and 900°C), with a process time between 80 min and 100 min (e.g., between 80 min and 90 min, between 90 min and 100 min). A temperature of high-temperature oxidation is between 950°C and 1050°C (e.g., between 950°C and 980°C, between 980°C and 1000°C, between 1000°C and 1050°C), which is higher than the temperature of boron diffusion, with a process time between 150 min and 170 min (e.g., between 150 min and 160 min, between 160 min and 170 min).

In some embodiments, the boron doping equipment includes a boron diffusion standalone station or a single boron diffusion station equipped with a high-temperature thermal field device, enabling both medium-temperature (e.g., between 700°C and 900°C) source diffusion and high-temperature (e.g., between 950°C and 1050°C) oxidation promotion functions in a single station. This approach typically has a process time between 160 min and 210 min (e.g., between 160 min and 180 min, between 180 min and 200 min, between 200 min and 210 min), effectively saving process time compared to separate stations for boron diffusion and high-temperature oxidation.

Step S14: removing the borosilicate glass layer from the second surface of the N-type silicon substrate, and performing polishing on the second surface of the N-type silicon substrate.

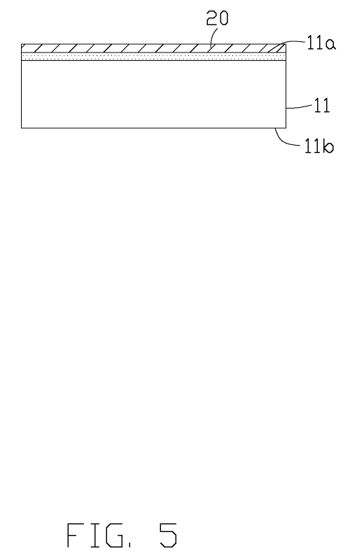

As shown in FIGS. 4 and 5, the BSG layer 20 on the second surface 11b of the N-type silicon substrate 11 is removed, while the BSG layer 20 on the first surface 11a is retained.

It should be noted that, as discussed above, during boron doping of the N-type silicon substrate 11, by-products including boron-doped polycrystalline silicon layers 12 and BSG layers 20 are also formed on the second surface 11b and the side surface 11c of the N-type silicon substrate 11.The boron-doped polycrystalline silicon layer 12 and the BSG layer 20 on the second surface 11b will affect subsequent passivation, and the boron-doped polycrystalline silicon layer 12 and the BSG layer 20 on the side surface 11c are likely to cause short circuits. Therefore, the boron-doped polycrystalline silicon layers 12 and the BSG layers 20 on the second surface 11b and the side surface 11c of the N-type silicon substrate 11 need to be removed.

In some embodiments, a chain-type BSG removal station (hereinafter also referred to as a first chain-type acid polishing equipment) with a hydrofluoric acid solution is used for etching with the first surface 11a facing upward, to remove the BSG layer on the second surface 11b and the side surface 11c. Then, the N-type silicon substrate 11 is etched by a tank-type polishing station (hereinafter also referred to as a first tank-type polishing equipment) with an alkaline solution for etching to remove the boron-doped polycrystalline silicon layer 12 on the second surface 11b and the side surface 11c.

In some embodiments, a chain-type BSG removal station combined with an alkali polishing station is used to polish the second surface 11b of the N-type silicon substrate 11 to remove the boron-doped polycrystalline silicon layer 12 and the BSG layer 20 on the side surface 11c and the second surface 11b of the N-type silicon substrate 11, thereby preparing for the doped polycrystalline silicon layer on the second surface 11b.

In some embodiments, a roller speed of the chain-type BSG removal station is controlled to 3 m/min to 5 m/min, with the roller transporting a single side (the second surface 11b) of the N-type silicon substrate 11 into a hydrofluoric acid solution with a conductivity of 400 mS/cm to 600 mS/cm, immersing the second surface 11b of the N-type silicon substrate 11 in the hydrofluoric acid solution for a preset time to remove the BSG layer 20 formed by wrap-around plating on the second surface 11b and the side surface 11c. Then, the N-type silicon substrate 11 is transferred to the tank-type polishing station, and placed in a alkali polishing solution containing KOH or NaOH or TMAH and corresponding additives to remove the boron-doped polycrystalline silicon layer 12 formed by wrap-around plating on the second surface 11b and the side surface 11c. A etching depth of the N-type silicon substrate 11 is controlled to between 2 μm and 5 μm (e.g., between 2 μm and 3 μm, between 3 μm and 4 μm, between 4 μm and 5 μm).

Step S15: forming a tunnel oxide layer, a phosphorus-doped polycrystalline silicon layer, and a mask layer on the second surface of the N-type silicon substrate.

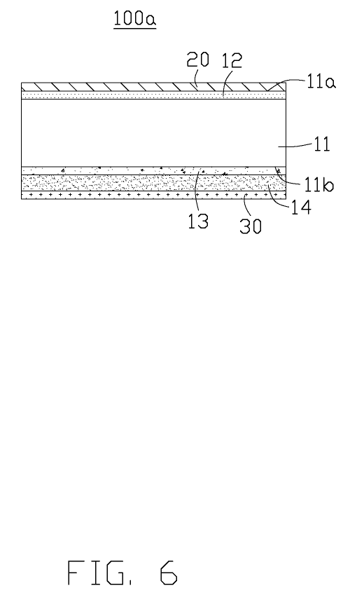

As shown in FIG. 6, the tunnel oxide layer 13, the phosphorus-doped polycrystalline silicon layer 14, and the mask layer 30 are sequentially stacked as stated on the second surface 11b of the N-type silicon substrate 11 along a direction away from the N-type silicon substrate 11. The stack 100a includes the N-type silicon substrate 11, the tunnel oxide layer 13, the phosphorus-doped polycrystalline silicon layer 14, the mask layer 30, and the BSG layer 20 on the first surface 11a of the N-type silicon substrate 11.

In some embodiments, the manner of the equipment combination used in step S15 (hereinafter also referred to as phosphorus doping equipment) includes, but is not limited to, the following Modes One to Four.

Mode One: preparing the phosphorus-doped polycrystalline silicon layer using a low-pressure chemical vapor deposition (LPCVD) equipment.

Mode Two: preparing an intrinsic polycrystalline silicon using a LPCVD, followed by performing a phosphorus diffusion process using a phosphorus diffusion equipment.

Mode Three: preparing doped amorphous silicon using a plasma enhanced chemical vapor deposition (PECVD) equipment (hereinafter also referred to as a first PECVD equipment), followed by performing an annealing process using an annealing process to convert the doped amorphous silicon into doped polycrystalline silicon.

Mode Four: preparing doped amorphous silicon using a physical vapor deposition (PVD) equipment, followed by performing an annealing process using an annealing equipment to convert the doped amorphous silicon into doped polycrystalline silicon.

In some embodiments, step S15 adopts Mode One, and includes: forming the tunnel oxide layer 13 on the second surface 11b of the N-type silicon substrate 11 using LPCVD technology, and introducing a phosphorus source and a silicon source to deposit a doped polycrystalline silicon layer on the tunnel oxide layer 13.

In some embodiments, step S15 adopts Mode Two. When preparing the intrinsic polycrystalline silicon on the side where the second surface 11b of the N-type silicon substrate 11 is located using LPCVD, intrinsic polycrystalline silicon layers are also formed on both the first surface 11a and the side surface 11c. During phosphorus diffusion on the second surface 11b, the intrinsic polycrystalline silicon on each the first surface 11a and the side surface 11c is converted into a phosphorus-doped polycrystalline silicon layer, and a phosphosilicate glass (PSG) layer is formed on the outermost side of the phosphorus-doped polycrystalline silicon layer on the first surface 11a and the side surface 11c, as well as the phosphorus-doped polycrystalline silicon layer 14 on the second surface 11b. Thus, the PSG layer on the second surface 11b can serve as the mask layer 30.

It can be understood that, depending on the different methods used in step S15 for preparing the phosphorus-doped polycrystalline silicon layer, the by-products formed on the N-type silicon substrate 11 will differ, and the material of the mask layer 30 will also differ accordingly. For example, when Mode Three is adopted, the material of the mask layer 30 includes at least one of PSG, silicon oxide, silicon oxynitride, and silicon nitride. Silicon oxide, silicon nitride, and silicon oxynitride can be formed by introducing gases containing corresponding elements during the execution of step S15, such as one or more of O₂, N₂, NO, NH₃, N₂O, and SiH₄. For example, when Mode Four is adopted, the mask layer 30 may be, but is not limited to, a silicon oxide layer formed by PVD.

In some embodiments, after the phosphorus-doped polycrystalline silicon layer 14 is formed, the phosphorus doping concentration on the second surface 11b is controlled to be greater than 2×10²⁰ cm⁻³.

In some embodiments, the tunnel oxide layer 13 is silicon oxide, and a thickness of the tunnel oxide layer 13 is between 1.5 nm and 2.5 nm (e.g., between 1.5 nm and 2 nm, between 2 nm and 2.5 nm).

In some embodiments, a thickness of the phosphorus-doped polycrystalline silicon layer 14 is between 60 nm and 200 nm (e.g., between 60 nm and 80 nm, between 80 nm and 100 nm, between 100 nm and 150 nm, between 150 nm and 200 nm).

In Block S2, through holes are formed in the mask layer, wherein each of the through holes exposes the phosphorus-doped polycrystalline silicon layer.

In some embodiments, the step of forming through holes in the mask layer includes performing laser ablation on the mask layer. Hereinafter, the laser equipment in the laser ablation process is referred to as a first laser equipment.

In some embodiments, in the laser ablation step, the specific parameters are:: using a green laser light source with a laser power between 80 W and 200 W (e.g., between 80 W and 100 W, between 100 W and 150 W, between 150 W and 200 W), a laser pulse frequency between 400 kHz and 1000 kHz (e.g., between 400 kHz and 500 kHz, between 500 kHz and 800 kHz, between 800 kHz and 1000 kHz), a peak energy between 1 μJ and 1 mJ (e.g., between 1 μJ and 800 μJ, between 800 μJ and 500 μJ, between 500 μJ and 100 μJ, between 100 μJ and 50 μJ, between 50 μJ and 10 μJ, between 10 μJ and 1 μJ), and a laser spot is a rectangular spot or a square spot, with the side length of the square spot between 100 μm and 600 μm (e.g., between 100 μm and 200 μm, between 200 μm and 300 μm, between 300 μm and 400 μm, between 400 μm and 500 μm, between 500 μm and 600 μm).

In the above laser ablation process, the use of a green laser light source is beneficial for reducing costs, stable operation, and high controllability.

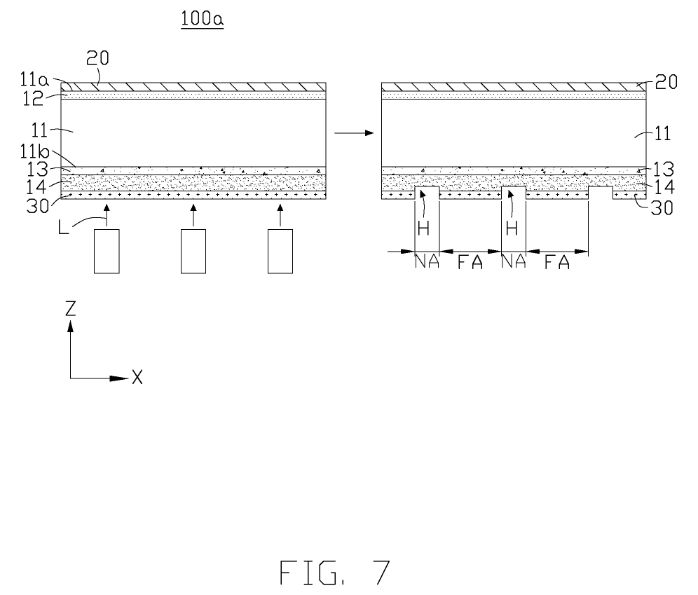

As shown in FIG. 7, each laser beam L is aligned with a local region of the mask layer 30 to remove the local region of the mask layer 30, forming through holes H penetrating the mask layer 30. The through holes H are spaced apart from each other along a first direction X. The first direction X is perpendicular to a thickness direction Z of the N-type silicon substrate 11.

In some embodiments, the region between two adjacent through holes H is used to form grid lines in subsequent steps, so the region between two adjacent through holes H is also referred to as a grid line region FA, and the region corresponding to the through hole H is also referred to as a non-grid line region NA. Each grid line region FA is alternated with one non-grid line region NA along the first direction X.

In some embodiments, in the step of forming the through holes H, a portion of the phosphorus-doped polycrystalline silicon layer 14 is removed, and each of the through holes H further extends into the phosphorus-doped polycrystalline silicon layer 14.

In Block S3, grooves are formed at the through holes, wherein each of the grooves and the through holes are arranged in a one-to one correspondence, and each of the grooves extends through the phosphorus-doped polycrystalline silicon layer and the tunnel oxide layer and partially extends into the N-type silicon substrate.

In some embodiments, forming the grooves includes placing the stack into an alkaline solution, and etching with the alkaline solution to remove the phosphorus-doped polycrystalline silicon layer, the tunnel oxide layer, and a portion of the N-type silicon substrate corresponding to the through holes, thereby forming the grooves.

In some embodiments, a chain-type PSG removal station (hereinafter also referred to as a second chain-type acid polishing equipment) and a tank-type polishing station (hereinafter also referred to as a second tank-type polishing equipment) are used to etch and remove the polycrystalline silicon layer or the mask layer (the mask layer may include PSG and BSG formed by boron diffusion) wrap-around plated on the first surface 11a of the N-type silicon substrate 11, the n+ layer or the mask layer (the mask layer may include PSG) on the side surface 11c, and the phosphorus-doped polycrystalline silicon layer, the tunnel oxide layer, and a portion of the N-type silicon substrate in the ablated region of the second surface 11b.

In some embodiments, the stack is placed into the chain-type PSG removal station, with the roller speed controlled at 3.2 m/min to 4.6 m/min, and the rollers transport the N-type silicon substrate 11 such that one side is immersed in a hydrofluoric acid solution with a conductivity of 60 mS/cm to 180 mS/cm, with the second surface 11b of the N-type silicon substrate 11 facing upward, and the first surface 11a of the N-type silicon substrate 11 immersed in the hydrofluoric acid solution for 1 min to 2 min, to remove the PSG formed by wrap-around plating on the first surface 11a and the side surface 11c. Then, the stack is transferred to the alkaline solution in the alkaline solution tank of the tank-type polishing station, where the alkaline solution is composed of KOH or NaOH or TMAH and corresponding additives, and the polycrystalline silicon layer wrap-around plated on the first surface 11a is completely removed, while the phosphorus-doped polycrystalline silicon layer, the tunnel oxide layer, and a portion of the N-type silicon substrate 11 in the laser ablated region of the second surface 11b are etched, thereby forming the grooves.

In some embodiments, in the step of forming the grooves, a pH value of the alkaline solution is adjusted by KOH or NaOH or TMAH so that the pH value of the alkaline solution is between 11.8 and 13 (e.g., between 11.8 and 12, between 12 and 12.5, between 12.5 and 13), and an etching time of the stack in the alkaline solution is controlled to be between 4 min and 10 min (e.g., between 4 min and 5 min, between 5 min and 6 min, between 6 min and 7 min, between 7 min and 8 min, between 8 min and 9 min, between 9 min and 10 min), so as to etch a portion of the N-type silicon substrate 11, thereby forming the grooves.

It should be noted that, in the step of forming the grooves, within a certain range, the higher the pH value, the higher the concentration of hydroxide ions in the alkaline solution, and the faster the etching reaction rate. Therefore, under the same other conditions (e.g., etching time), using a solution with a higher pH value (e.g., increasing from 11.8 to 13) will result in a faster etching rate, thereby obtaining deeper grooves in the same time. Additionally, within a certain range, when other conditions (e.g., pH value) remain constant, the longer the etching time, the longer the contact reaction time between the silicon substrate and the alkaline solution, the more silicon is corroded, and the deeper the formed grooves. Therefore, in the step of forming the grooves, the depth of the grooves can be controlled by the combination of the pH value of the alkaline solution and the etching time of the stack in the alkaline solution. For example, forming a groove of medium depth (e.g., 2 μm) can be achieved by selecting “higher pH value combined with shorter etching time” (e.g., pH value between 12 and 13, etching time between 4 min and 7 min) within the above pH value and etching time ranges, or by “lower pH value combined with longer etching time” (e.g., pH value between 11.8 and 12, etching time between 7 min and 10 min).

As shown in FIGS. 7 and, each groove R is formed corresponding to one through hole H. Each groove R penetrates the phosphorus-doped polycrystalline silicon layer 14 and the tunnel oxide layer 13 and partially extends into the N-type silicon substrate 11. The N-type silicon substrate 11 forms a bottom wall of each groove R. The N-type silicon substrate 11, the phosphorus-doped polycrystalline silicon layer 14, and the tunnel oxide layer 13 together form side walls of each groove R.

In some embodiments, a depth D of each groove R is between 1 μm and 3 μm (e.g., between 1 μm and 1.5 μm, between 1.5 μm and 2 μm, between 2 μm and 2.5 μm, between 2.5 μm and 3 μm, etc.).

Through the grooves R, the surface of the stack 100a provided with the phosphorus-doped polycrystalline silicon layer 14 is divided into spaced emitter regions. The emitter regions are used for arranging back grid lines. When subsequently arranging front grid lines and back grid lines, along the thickness direction Z of the N-type silicon substrate 11, projections of the contact region between the back grid lines and the phosphorus-doped polycrystalline silicon layer 14 do not overlap with the projections of the grooves R.

Photons entering the solar cell through irradiation from the first surface need to undergo the photovoltaic effect at the PN junction to generate photogenic charge carriers. The photogenic charge carriers need to circulate inside the solar cell and be emitted through the emitter (corresponding to the regions where the front grid lines and back grid lines of the present disclosure are located). By etching the tunnel oxide layer 13 at the positions of the grooves R, a lateral transport of photogenic charge carriers in the tunnel oxide layer and the sidewalls of the tunnel oxide layer can be reduced, thereby reducing charge carrier recombination. Furthermore, photons are guided to positions close to the emitter to generate photogenic charge carriers, shortening the circulation path of photogenic charge carriers, and maximizing the use of the built-in electric field of the PN junction along the thickness direction as much as possible to guide the separation and diffusion of photogenic charge carriers, thereby reducing carrier recombination and improving efficiency.

In Block S4, the mask layer is removed.

In some embodiments, removing the mask layer includes at least partially immersing the stack in a hydrofluoric acid solution, and removing the mask layer through the hydrofluoric acid solution.

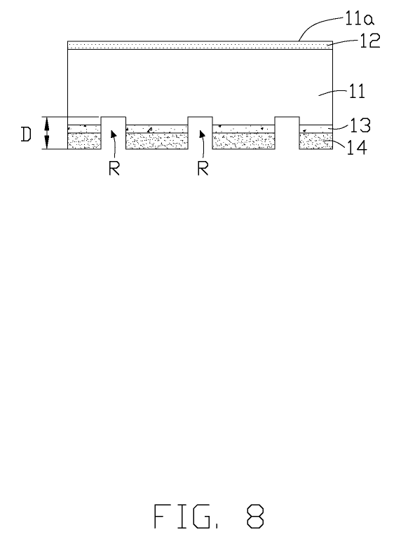

Continuing to refer to FIGS. 7 and 8, the mask layer 30 on the second surface 11b of the N-type silicon substrate 11 is removed. Additionally, the BSG layer 20 on the first surface 11a of the N-type silicon substrate 11 is removed.

In some embodiments, the stack having the grooves is placed in a hydrofluoric acid tank of the tank-type polishing station for etching treatment to remove the BSG on the first surface 11a and the mask layer 30 (such as PSG) on the second surface 11b.

In some embodiments, after removing the mask layer, the method for preparing the solar cell further includes forming a front passivation layer on the first surface of the N-type silicon substrate and forming a back passivation layer on the second surface of the N-type silicon substrate.

In some embodiments, double-sided deposition is performed on the N-type silicon substrate to form the front passivation layer and the back passivation layer.

In some embodiments, deposition equipment, such as atomic layer deposition (ALD) equipment or PECVD equipment, is used to deposit a passivation layer on the first surface 11a of the silicon substrate, or to deposit passivation layers on both the first surface 11a and the second surface 11b of the silicon substrate.

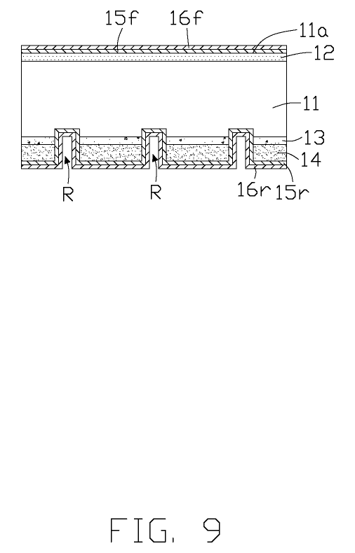

As shown in FIG. 9, the front passivation layer 15f is in contact with the first surface 11a of the N-type silicon substrate 11, and the back passivation layer 15r covers the phosphorus-doped polycrystalline silicon layer 14 and inner walls of each groove R. The back passivation layer 15r is in contact with a surface of the doped polycrystalline silicon layer 14 away from the N-type silicon substrate 11, the bottom wall of each groove R (i.e., the N-type silicon substrate 11), and the side walls of each groove R (i.e., the N-type silicon substrate 11, the tunnel oxide layer 13, and the phosphorus-doped polycrystalline silicon layer 14).

In some embodiments, a thickness of the front passivation layer 15f is between 2 nm and 8 nm, and a material of the front passivation layer 15f may be, but is not limited to, aluminum oxide.

In some embodiments, a thickness of the back passivation layer 15r is between 2 nm and 8 nm, and a material of the front passivation layer 15f may be, but is not limited to, aluminum oxide.

In some embodiments, after forming the front passivation layer and the back passivation layer, the method for preparing the solar cell further includes forming a front anti-reflection layer on the first surface of the N-type silicon substrate and forming a back anti-reflection layer on the second surface of the N-type silicon substrate.

In some embodiments, deposition equipment, such as PECVD equipment, is used to deposit the anti-reflection layer on the first surface 11a and/or the second surface 11b of the N-type silicon substrate 11. It should be noted that, to distinguish from the PECVD equipment of Mode Three in step S15, the PECVD equipment for forming the passivation layer or anti-reflection layer is also referred to as a second PECVD equipment.

As shown in FIG. 9, the front anti-reflection layer 16f is on the front passivation layer 15f, and the back anti-reflection layer 16r is on the back passivation layer 15r.

In some embodiments, a material of each of the front anti-reflection layer 16f and the back anti-reflection layer 16r includes at least one of Si_{y}Nₓ, Si_{z}NₓO_{y}, and SiO₂, and both the front anti-reflection layer 16f and the back anti-reflection layer 16r have functions of reducing reflection and increasing transmission.

In some embodiments, a deposition thickness of each of the front anti-reflection layer 16f and/or the back anti-reflection layer 16r is controlled to between 70 nm and 90 nm.

In block S5, front grid lines and disposing back grid lines are arranged.

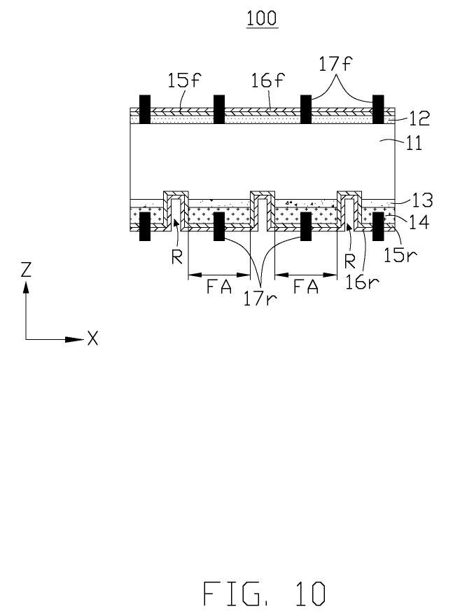

As shown in FIG. 10, a side of the solar cell corresponding to the first surface 11a is defined as a front side, and a side of the solar cell corresponding to the second surface 11b is defined as a back side. The front grid lines are arranged on the front side, and the back grid lines are arranged on the back side. The front grid lines 17f are spaced apart from each other along the first direction X, and each front grid line 17f is in contact with the boron-doped polycrystalline silicon layer 12 and forms an ohmic contact. The back grid lines 17r are spaced apart from each other along the first direction X, and each back grid line 17r is formed in a corresponding grid line region FA. Each of the grooves R is alternated with one of the back grid lines 17r along the first direction X. Each back grid line 17r is in contact with the phosphorus-doped polycrystalline silicon layer 14 and forms an ohmic contact. Along the thickness direction Z of the N-type silicon substrate 11, a projection of a contact region between each back grid line 17r and the phosphorus-doped polycrystalline silicon layer 14 does not overlap with the projection of the grooves R. Thus, the solar cell 100 is obtained.

In some embodiments, arranging the front grid lines includes using metal equipment (e.g., printing equipment) to print conductive metal paste on the first surface 11a, and performing laser-enhanced contact optimization (LECO) using the second laser equipment to cure the conductive metal paste on the first surface 11a, and allow metal atoms in the conductive metal paste contact the N-type silicon substrate 11, thereby forming the front grid lines 17f.

In some embodiments, in the step of arranging the front grid lines, the conductive metal paste is printed on the front anti-reflection layer 16f, and during the sintering process, the metal atoms in the conductive metal paste on the first surface 11a pass through the front passivation layer 15f and the front anti-reflection layer 16f to contact the N-type silicon substrate 11.

In some embodiments, arranging the back grid lines includes using metal equipment (e.g., printing equipment) to print conductive metal paste on the second surface 11b, and performing LECO using the second laser equipment to cure the conductive metal paste on the second surface 11b, and allow the metal atoms in the conductive metal paste contact the N-type silicon substrate 11, thereby forming the back grid lines 17r.

In some embodiments, in the step of arranging the back grid lines, the conductive metal paste is printed on the back anti-reflection layer 16r, and during the sintering process, the metal atoms in the conductive metal paste on the second surface 11b pass through the back passivation layer 15r and the back anti-reflection layer 16r to contact the N-type silicon substrate 11.

In some embodiments, laser scanning is used on the front grid lines of the solar cell, while applying a deflection voltage (reverse bias voltage) of 10 V or more, wherein an electric field direction of the external electric field is opposite to an electric field direction of the built-in electric field of the N-type crystalline silicon solar cell.

In some embodiments, the time for applying the voltage is a total duration between 0.3 s and 3 s (e.g., between 0.3 s and 1 s, between 1 s and 2 s, between 2 s and 3 s) for a single cell, and the effective time (i.e., time when current is applied per unit area under laser irradiation) is about between 10 μs and 20 μs (e.g., between 10 μs and 14 μs, between 14 μs and 17 μs, between 17 μs and 20 μs).

In some embodiments, a laser type of the second laser equipment is infrared pulse laser.

In some embodiments, a laser power of the second laser equipment is between 50 W and 150 W (e.g., between 50 W and 60 W, between 60 W and 70 W, between 70 W and 80 W, between 80 W and 90 W, between 90 W and 100 W).

In some embodiments, a laser pulse frequency of the second laser equipment is between 10 kHz to 50000 kHz (e.g., between 10 kHz and 100 kHz, between 100 kHz and 1000 kHz, between 1000 kHz and 5000 kHz, between 5000 kHz and 10000 kHz, between 10000 kHz and 20000 kHz, between 20000 kHz and 50000 kHz).

In some embodiments, a laser scanning speed of the second laser equipment is between 20000 mm/s and 60000 mm/s (e.g., between 20000 mm/s and 30000 mm/s, between 30000 mm/s and 40000 mm/s, between 40000 mm/s and 50000 mm/s, between 50000 mm/s and 60000 mm/s).

In some embodiments, a laser peak energy of the second laser equipment is between 1 μJ and 1 mJ (e.g., between 1 μJ and 800 μJ, between 800 μJ and 500 μJ, between 500 μJ and 100 μJ, between 100 μJ and 50 μJ, between 50 μJ and 10 μJ, between 10 μJ and 1 μJ).

In some embodiments, a laser spot of the second laser equipment is a strip-shaped spot, with a length of the strip-shaped spot between 1.2 mm and 210 mm (e.g., between 1.2 mm and 10 mm, between 10 mm and 50 mm, between 50 mm and 100 mm, between 100 mm and 150 mm, between 150 mm and 180 mm, between 180 mm and 210 mm), and a width of the strip-shaped spot between 80 μm and 1000 μm (e.g., between 80 μm and 100 μm, between 100 μm and 200 μm, between 200 μm and 300 μm, between 300 μm and 400 μm, between 400 μm and 500 μm, between 500 μm and 600 μm, between 600 μm and 800 μm, between 800 μm and 1000 μm).

In some embodiments, a sintering temperature of the front grid lines and the back grid lines is between 760°C and 880°C (e.g., between 760°C and 770°C, between 770°C and 780°C, between 780°C and 790°C, between 790°C and 800°C, between 800°C and 810°C, between 810°C and 820°C, between 820°C and 830°C, between 830°C and 840°C, between 840°C and 850°C, between 850°C and 860°C, between 860°C and 870°C, between 870°C and 880°C).

In some embodiments, after forming the front grid lines and the back grid lines, the method further includes testing, sorting, and storing the solar cell.

It should be noted that, in conventional TOPCon cells, due to a design of full-area passivation layer on the second surface, the high-temperature sintering mechanism of metallization limits the reduction in the thickness of the doped polycrystalline silicon layer. In TOPCon cells, due to parasitic absorption by the polysilicon, the utilization rate of incident light on the second surface is low (bifacial utilization typically less than 80%). To address the technical bottlenecks of TOPCon cells in terms of optical utilization on the second surface and the bifacial utilization, in the method for preparing the solar cell according to the embodiments of the present disclosure, grooves are formed on the second surface that penetrate the phosphorus-doped polycrystalline silicon layer and the tunnel oxide layer and partially extend into the N-type silicon substrate, so that there is no tunnel passivation contact structure at the grooves on the second surface of the solar cell. Compared with the design of the full-area tunnel passivation contact structure on the second surface of traditional TOPCon solar cells, this can reduce the parasitic absorption of polycrystalline silicon on the second surface of the solar cell, thereby improving the optical utilization rate on the second surface of the solar cell, and increasing the bifacial utilization and cell efficiency of the solar cell.

In some embodiments, the bifacial utilization of the solar cell obtained by the method for preparing the solar cell is greater than 80%.

Embodiments of the present disclosure further provide a solar cell. The solar cell can be obtained by the above method for preparing a solar cell, but is not limited thereto. The solar cell includes an N-type silicon substrate, a tunnel oxide layer, a phosphorus-doped polycrystalline silicon layer, grooves, front grid lines, and back grid lines. The N-type silicon substrate includes a first surface and a second surface opposite to the first surface. A boron-doped polycrystalline silicon layer is formed in the N-type silicon substrate near the first surface. The tunnel oxide layer is in contact with the second surface. The phosphorus-doped polycrystalline silicon layer is on a surface of the tunnel oxide layer away from the N-type silicon substrate. The grooves penetrate the phosphorus-doped polycrystalline silicon layer and the tunnel oxide layer and partially extend into the N-type silicon substrate. The front grid lines are in contact with the boron-doped polycrystalline silicon layer. The back grid lines are in contact with the phosphorus-doped polycrystalline silicon layer, and along a thickness direction of the N-type silicon substrate, projections of contact regions between the back grid lines and the phosphorus-doped polycrystalline silicon layer do not overlap with projections of the grooves.

In some embodiments, the solar cell further includes a back passivation layer, wherein the back passivation layer covers the phosphorus-doped polycrystalline silicon layer and inner walls of the grooves.

In some embodiments, a depth of each of the grooves is 1 μm to 3 μm, but is not limited thereto.

Embodiments of the present disclosure further provide a photovoltaic module (not shown). The photovoltaic module includes at least two solar cells. The solar cells can be obtained by the above method for preparing a solar cell, but are not limited thereto.

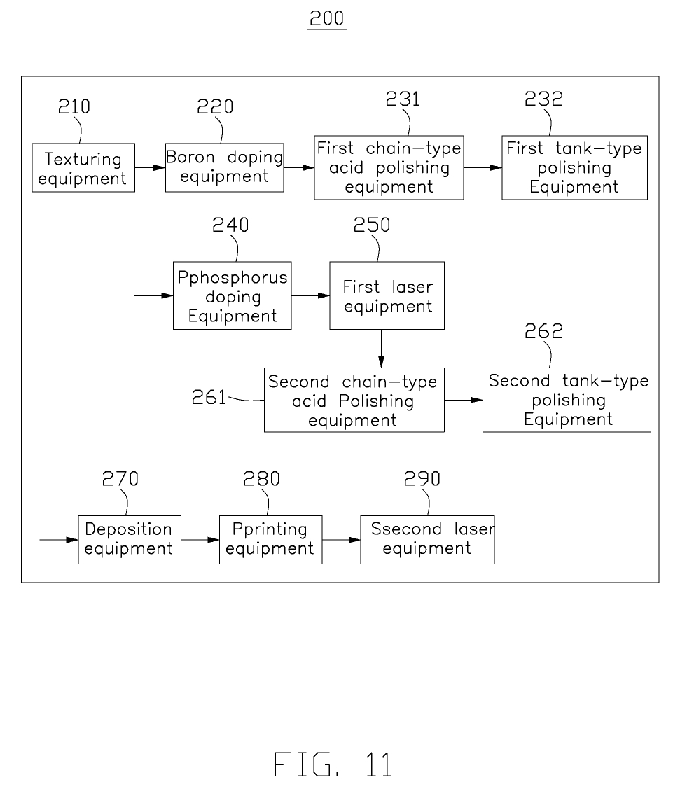

As shown in FIG. 11, embodiments of the present disclosure further provide a solar cell production line 200. The solar cell production line 200 can be used to implement the above method for preparing a solar cell. The solar cell production line 200 includes the following equipment sequentially connected: a texturing equipment 210, a boron doping equipment 220, a first chain-type acid polishing equipment 231, a first tank-type polishing equipment 232, a phosphorus doping equipment 240, a first laser equipment 250, a second chain-type acid polishing equipment 261, a second tank-type polishing equipment 262, a deposition equipment 270, a printing equipment 280, and a second laser equipment 290.

The texturing equipment 210 is used for performing texturing treatment on the N-type silicon substrate.

In some embodiments, the texturing equipment 210 includes a wet-process station.

The boron doping equipment 220 is used for performing boron doping treatment on the N-type silicon substrate to form a boron-doped polycrystalline silicon layer in the N-type silicon substrate near the first surface.

In some embodiments, the boron doping equipment 220 includes a boron diffusion standalone station.

In some embodiments, the boron doping equipment 220 includes a combination of a boron diffusion station and an oxidation station.

The first chain-type acid polishing equipment 231 is used for removing the borosilicate glass layer on the second surface of the N-type silicon substrate.

The first tank-type polishing equipment 232 is used for polishing treatment on the second surface of the N-type silicon substrate.

The phosphorus doping equipment 240 is used for forming a tunnel oxide layer, a phosphorus-doped polycrystalline silicon layer, and a mask layer on the second surface of the N-type silicon substrate.

In some embodiments, the phosphorus doping equipment 220 includes low-pressure chemical vapor deposition equipment.

In some embodiments, the phosphorus doping equipment 220 includes low-pressure chemical vapor deposition equipment and phosphorus diffusion equipment.

In some embodiments, the phosphorus doping equipment 220 includes a first plasma chemical vapor deposition equipment and an annealing equipment.

In some embodiments, the phosphorus doping equipment 220 includes a physical vapor deposition equipment and an annealing equipment.

The first laser equipment 250 is used for ablating local regions of the mask layer to form through holes exposing the phosphorus-doped polycrystalline silicon layer.

The second chain-type acid polishing equipment 261 is used for removing the phosphosilicate glass layer on the first surface of the N-type silicon substrate.

The second tank-type polishing equipment 262 includes an alkaline solution tank (not shown) for containing an alkaline solution and a hydrofluoric acid tank (not shown) for containing a hydrofluoric acid solution, to etch and remove the phosphorus-doped polycrystalline silicon layer, the tunnel oxide layer, and a portion of the N-type silicon substrate corresponding to the through holes through the alkaline solution, thereby forming grooves penetrating the phosphorus-doped polycrystalline silicon layer and the tunnel oxide layer and partially extending into the N-type silicon substrate, and to remove the mask layer through the hydrofluoric acid solution.

The deposition equipment 270 is used for forming a front passivation layer and/or a front anti-reflection layer on the first surface of the N-type silicon substrate, and/or forming a back passivation layer and/or a back anti-reflection layer on the second surface of the N-type silicon substrate.

In some embodiments, the deposition equipment 270 includes an atomic layer deposition equipment.

In some embodiments, the deposition equipment 270 includes second plasma chemical vapor deposition equipment.

The printing equipment 280 is used for forming front grid lines on the first surface of the N-type silicon substrate and forming back grid lines on the second surface of the N-type silicon substrate.

The second laser equipment 290 is used for performing assisted sintering on the front grid lines and the back grid lines.

In some embodiments, the structures and process parameters of each equipment (such as the texturing equipment 210, the boron doping equipment 220, etc.) included in the solar cell production line 200 can refer to the above description of the method for preparing the solar cell, which will not be repeated here.

It is to be understood, even though information and advantages of the present exemplary embodiments have been set forth in the foregoing description, together with details of the structures and functions of the present exemplary embodiments, the disclosure is illustrative only . Changes may be made in detail, especially in matters of shape, size, and arrangement of parts within the principles of the present exemplary embodiments to the full extent indicated by the plain meaning of the terms in which the appended claims are expressed.

What is claimed is:

1. A method of preparing a solar cell comprising:
providing a stack comprising an N-type silicon substrate, a tunnel oxide layer, a phosphorus-doped polycrystalline silicon layer, and a mask layer;
wherein the N-type silicon substrate comprises a first surface and a second surface opposite to the first surface, a boron-doped polycrystalline silicon layer is formed in the N-type silicon substrate at a depth close to the first surface;
and the tunnel oxide layer, the phosphorus-doped polycrystalline silicon layer, and the mask layer are stacked as stated on the second surface along a direction away from the N-type silicon substrate;
forming through holes exposing the phosphorus-doped polycrystalline silicon layer in the mask layer;
forming grooves one-to-one corresponding to the through holes, wherein each of the grooves extends through the phosphorus-doped polycrystalline silicon layer and the tunnel oxide layer and partially extends into the N-type silicon substrate, and a surface of the stack provided with the phosphorus-doped polycrystalline silicon layer comprises emitter regions separated by the grooves; and
removing the mask layer.

2. The method as claimed in claim 1, wherein forming the through holes comprises performing laser ablation on the mask layer using a green laser source with a laser power between 80 W and 200 W, a laser pulse frequency between 400 kHz and 1000 kHz, a peak energy between 1 μJ and 1 mJ, and a laser spot side length between 100 μm and 600 μm.

3. The method as claimed in claim 1, wherein forming the grooves comprises:
placing the stack into an alkaline solution, and
etching the stack with the alkaline solution to remove the phosphorus-doped polycrystalline silicon layer, the tunnel oxide layer, and part of the N-type silicon substrate corresponding to the through holes, thereby forming the grooves.

4. The method as claimed in claim 3, wherein a depth of each of the grooves is controlled in a range from 1 μm to 3 μm by adjusting a pH value of the alkaline solution and an etching time of the stack.

5. The method as claimed in claim 3, wherein forming the grooves further comprises: selecting the alkaline solution with a PH value between 11.8 and 13, and etching the stack for 4 min to 10 min.

6. The method as claimed in claim 1, wherein removing the mask layer comprises at least partially immersing the stack in a hydrofluoric acid solution, and removing the mask layer with the hydrofluoric acid solution.

7. The method as claimed in claim 1, after removing the mask layer, further comprising:
performing double-sided deposition on the N-type silicon substrate to form a front passivation layer on the first surface and a back passivation layer on the second surface, wherein the back passivation layer covers the phosphorus-doped polycrystalline silicon layer and inner walls of the grooves.

8. The method as claimed in claim 1, after removing the mask layer, further comprising:
arranging front grid lines in contact with the boron-doped polycrystalline silicon layer and arranging back grid lines in contact with the phosphorus-doped polycrystalline silicon layer in the emitter regions.

9. The method as claimed in claim 8, wherein the solar cell has a front side corresponding to the first surface and a back side corresponding to the second surface;
forming the front grid lines comprises printing a first conductive metal paste on the front side, and curing the first conductive metal paste by laser-assisted sintering to form the front grid lines;
forming the back grid lines comprise printing a second conductive metal paste on the back side, and curing the second conductive metal paste by laser-assisted sintering to form the back grid lines.

10. A solar cell comprising:
an N-type silicon substrate comprising a first surface and a second surface opposite to the first surface, wherein a boron-doped polycrystalline silicon layer is in the N-type silicon substrate at a depth close to the first surface;
a tunnel oxide layer in contact with the second surface;
a phosphorus-doped polycrystalline silicon layer on a surface of the tunnel oxide layer away from the N-type silicon substrate;
grooves extending through the phosphorus-doped polycrystalline silicon layer and the tunnel oxide layer and partially extending into the N-type silicon substrate;
front grid lines in contact with the boron-doped polycrystalline silicon layer; and
back grid lines in contact with the phosphorus-doped polycrystalline silicon layer, wherein in a thickness direction of the N-type silicon substrate, projections of contact regions between the back grid lines and the phosphorus-doped polycrystalline silicon layer do not overlap with projections of the grooves.

11. The solar cell according to claim 10, further comprising a back passivation layer covering the phosphorus-doped polycrystalline silicon layer and inner walls of the grooves.

12. The solar cell according to claim 10, wherein a depth of each of the grooves ranges from 1 μm to 3 μm.

13. The solar cell according to claim 11, further comprising a back anti-reflection layer covering the back passivation layer and extending into the grooves to cover the inner walls.

14. The solar cell according to claim 13, further comprising a front passivation layer on the first surface.

15. The solar cell according to claim 14, further comprising a front anti-reflection layer on the front passivation layer.

16. A solar cell production line comprising sequentially connected:
a texturing equipment configured for texturing an N-type silicon substrate;
a boron doping equipment configured for boron doping the N-type silicon substrate to form a boron-doped polycrystalline silicon layer in the N-type silicon substrate close to a first surface;
a first chain-type acid polishing equipment configured for removing a borosilicate glass layer on a second surface of the N-type silicon substrate, the second surface being opposite to the first surface;
a first tank-type polishing equipment configured for polishing the second surface of the N-type silicon substrate;
a phosphorus doping equipment configured for forming a tunnel oxide layer, a phosphorus-doped polycrystalline silicon layer, and a mask layer on the second surface of the N-type silicon substrate;
a first laser equipment configured for performing laser ablation on the mask layer to form through holes each exposing the phosphorus-doped polycrystalline silicon layer;
a second chain-type acid polishing equipment configured for removing a phosphosilicate glass layer on the first surface of the N-type silicon substrate;
a second tank-type polishing equipment comprising an alkaline solution tank configured for containing an alkaline solution and a hydrofluoric acid tank configured for containing a hydrofluoric acid solution, so as to etch and remove the phosphorus-doped polycrystalline silicon layer, the tunnel oxide layer, and part of the N-type silicon substrate corresponding to the through holes using the alkaline solution, thereby forming grooves extending through the phosphorus-doped polycrystalline silicon layer and the tunnel oxide layer and partially extending into the N-type silicon substrate, and to remove the mask layer using the hydrofluoric acid solution;
a deposition equipment configured for forming a front passivation layer and/or a front anti-reflection layer on the first surface of the N-type silicon substrate, and/or forming a back passivation layer and/or a back anti-reflection layer on the second surface of the N-type silicon substrate;
a printing equipment configured for forming front grid lines on the first surface of the N-type silicon substrate and forming back grid lines on the second surface of the N-type silicon substrate; and
a second laser equipment configured for assisting sintering of the front grid lines and the back grid lines.

17. The solar cell production line according to claim 16, wherein the first laser equipment is a green laser source.

18. The solar cell production line according to claim 16, wherein the boron doping equipment comprises a single boron diffusion station, or a combination of a boron diffusion station and an oxidation station.

19. The solar cell production line according to claim 16, wherein the phosphorus doping equipment is a low-pressure chemical vapor deposition equipment; or the phosphorus doping equipment comprises a low-pressure chemical vapor deposition equipment and a phosphorus diffusion equipment; o the phosphorus doping equipment comprises a first plasma-enhanced chemical vapor deposition equipment and an annealing equipment; or the phosphorus doping equipment comprises a physical vapor deposition equipment and an annealing equipment.

20. The solar cell production line according to claim 16, wherein the deposition equipment comprises an atomic layer deposition equipment, or a second plasma-enhanced chemical vapor deposition equipment.
